(19) United States
(12) Patent Application Publication
(10) Pub. No.: US 2023/0284416 A1
(43) Pub. Date: Sep. 7, 2023

(54) Ship-and-Install Electronics Assembly with Multifunctional Interface Chassis and Liquid-Fluid Heat Exchange

(71) Applicant: JetCool Technologies Inc., Littleton, MA (US)

(72) Inventors: Bernard MALOUIN, Westford, MA (US); Jordan MIZERAK, Belmont, MA (US)

(73) Assignee: JetCool Technologies Inc., Littleton, MA (US)

(21) Appl. No.: 18/116,617

(22) Filed: Mar. 2, 2023

Related U.S. Application Data
(60) Provisional application No. 63/316,522, filed on Mar. 4, 2022.
(60) Provisional application No. 63/326,469, filed on Apr. 1, 2022.

(51) Int. Cl. H05K 7/20

(52) U.S. Cl. CPC H05K 7/20272; H05K 7/20254; H05K 7/20154; H05K 7/20145

(57) ABSTRACT

A ship-and-install electronics assembly with multifunctional interface chassis and liquid-fluid heat exchange. A liquid-fluid loop subassembly contains a pump, a liquid cooling implement, a liquid-fluid heat exchanger, and fluid conveyance components. An electrical circuit subassembly contains a heat-generating component. A multifunctional interface chassis facilitates at least two of structural, electrical power, electrical sensor signal, and network communication between the assembly and corresponding fixtures external to the assembly. Allows for implementation of high density heat-generating electronic components with liquid cooling in a modular form factor that is easy for end users to install and operate.

### TECHNICAL FIELD

Liquid cooled electronic assemblies, and more particularly scalable and modular liquid-cooled electronic assemblies that are shipping- and installation-ready.

### BACKGROUND

An electronics assembly is an assembled collection of integrated circuits, discrete electronic components, circuit elements, circuit boards and harnesses, etc. for an electronic device, such as a computer system. To improve the performance of computer systems used in applications such as supercomputing, artificial intelligence, networking, and other such applications, electronics assemblies are becoming more and more dense in terms of the number and size of all of the individual electronic components, circuits and traces. Because these electronic components and circuits are not perfectly energy-efficient, increasing the density of electronic components and circuits in electronic assemblies tends to increase the amount of waste heat that must be managed in the electronic assemblies. One popular technique for managing and removing waste heat generated in dense electronic assemblies is liquid cooling, in which liquid-based coolants with strong thermofluidic properties are directed to flow over the surfaces associated with heat-generating components in the electronic assemblies so that the coolants can absorb and carry away extraneous heat generated by the high density heat-generating devices.

However, there are several significant problems associated with conventional liquid-cooled electronics assemblies. For one thing, receiving, installing and maintaining a shipment of conventional liquid-cooled electronics assemblies tends to be a very arduous and time-consuming process for many electronic device operators. This is due to a variety of different factors. First, conventional liquid cooled electronics assemblies typically have a plurality of different components, each relating to independent and distinct areas of expertise (e.g. fluidic, electrical, structural, etc.), and each of which require expert installation to combine into a safe, functioning system. Second, many conventional liquid-cooled electronics assemblies usually require pre-installation and configuration of facility level fixtures and/or infrastructures to implement properly. Installing and configuring these fixtures and infrastructures frequently requires spending a considerable amount of time, effort and money before the shipments of the liquid-cooled electronics even arrive at the facility where they will be installed. Third, many conventional liquid-cooled electronics assemblies also require special logistics equipment for shipping, receiving and subsequent handling.

The result of having to deal with these and other obstacles associated with receiving, installing and operating conventional liquid-cooled electronics assemblies has led to many facilities deciding not to employ liquid-cooling technology for their electronic devices, thereby limiting their ability to purchase and use higher-preforming increasingly dense electronics assemblies in their processing-intense applications.

Therefore, there is a considerable need in the electronics and computing industries for a modular, shipping-ready, easy-to-install liquid-cooled electronics assembly. There is also a considerable need for more effective waste heat management in dense electronics assemblies that do not present as many infrastructure and operational obstacles that existing liquid cooling systems present. There also exists a tremendous need for more scalability in liquid-cooled electronics assemblies, which would permit users and operators to migrate to higher capacity, better-performing liquid-cooled electronics assemblies that take advantage of the latest innovations in component and circuit structure and density.

### SUMMARY

Embodiments of the present invention address the aforementioned problems and needs by providing a ship-ready and install-ready electronics assembly with multifunctional interface chassis and liquid-fluid heat exchange. In general, an electronics assembly according to one embodiment of the present invention comprises an electrical circuit subassembly, a liquid-fluid lop subassembly and a multifunctional interface chassis subassembly.

The electrical circuit assembly comprises a heat-generating component, such as a computer processor. The computer processor may comprise, for example, an application specific integrated circuit (ASIC), central processing unit (CPU), or graphics processing unit (GPU). The liquid-fluid loop subassembly comprises a pump, a liquid cooling implement and a liquid-fluid heat exchanger. The pump is configured to pressurize a liquid coolant. The liquid cooling implement is in fluidic communication with the pump and in direct thermal communication with the heat-generating electrical component. The liquid cooling implement is also configured to receive the liquid coolant from the pump at a first pressure and exhaust the liquid coolant at a second pressure that is lower than the first pressure so that the liquid coolant will absorb heat generated by the heat-generated component as the liquid coolant flows through the liquid cooling implement. In certain embodiments, the liquid cooling implement may comprise one or more internal features, such as nozzles, pin fins or channels, to enhance the removal of heat from the heat-generating device by the flow of liquid coolant.

The liquid-fluid heat exchanger, which is in fluidic communication with the liquid cooling implement and the pump, is configured to receive the liquid coolant from liquid cooling implement and remove the heat absorbed by the liquid coolant. The liquid-fluid heat exchanger may comprise a liquid-air heat exchanger, a liquid-liquid heat exchanger, or both. If the liquid-fluid heat exchanger comprises a liquid-air heat exchanger, the electronics assembly may further include a fan to accelerate air flowing through the liquid-air heat exchanger for increased heat removal, as well as an air containment system comprising, for example, at least one baffle and at least one air duct suitably configured to facilitate easy connection to air duct fixtures located in the computer system or installation facility.

The multifunctional interface chassis subassembly, which is electrically connected to the electrical circuit subassembly, the liquid-fluid loop subassembly and the liquid-fluid heat exchanger, comprises an electrical power port configured to be connected to an active external power fixture.

When the electrical power port on the multifunctional interface chassis subassembly is connected to the active external power fixture, the multifunctional interface chassis assembly will receive electrical power from the active external power fixture and deliver to the electrical circuit subassembly, the liquid-fluid loop subassembly and the liquid-fluid heat exchanger the electrical power required for the electrical circuit subassembly, the liquid-fluid loop subassembly and the liquid-fluid heat exchanger to operate.

In some embodiments, the multifunctional interface chassis subassembly is also communicatively coupled to the electrical circuit subassembly, the liquid-fluid loop subassembly, or both. Accordingly, the multifunctional interface chassis subassembly may further comprise a network port (and/or a network switch) configured to be communicatively coupled to an external data communications network. When the network port on the multifunctional interface chassis subassembly is connected to the external data communications network, the multifunctional interface chassis assembly will provide a data communications channel to carry data communications signals between the external data communications network and the electrical circuit subassembly, between the external data communications network and the liquid-fluid loop subassembly, or both.

In some embodiments, the electronics assembly of the present invention may further comprise one or more sensors for collecting data generated by the electronics assembly. The sensors may be located in the liquid-fluid loop subassembly, the electrical circuit subassembly, or both. The sensors may be configured to collect, for instance, temperature data and/or fluid flow data. In some embodiments, the sensors may also be configured to detect leaks of liquid coolant from the liquid-fluid loop subassembly.

### BRIEF DESCRIPTION OF THE DRAWINGS

For a better understanding of the present disclosure, reference is made to the accompanying drawings, in which:

FIG. 1 shows a block diagram of the ship-and-install electronics assembly with multifunctional interface chassis and liquid-fluid heat exchange according to an embodiment of the present invention.

FIG. 2 depicts an embodiment of a ship-and-install electronics assembly with multifunctional interface chassis and liquid-fluid heat exchange in schematic form.

FIG. 3 depicts another embodiment of a ship-and-install electronics assembly with multifunctional interface chassis and liquid-fluid heat exchange according to another embodiment of the present invention.

FIGS. 4A and 4B depict internal and external views, respectively, of a liquid cooling implement that might be put into thermal communication with a heat-generating device in embodiments of the present invention.

FIG. 5 depicts another embodiment of a ship-and-install electronics assembly with multifunctional interface chassis and liquid-fluid heat exchange in schematic form containing an air duct.

FIG. 6 depicts another embodiment of a ship-and-install electronics assembly with multifunctional interface chassis and liquid-fluid heat exchange in schematic form with a liquid-liquid heat exchanger.

FIG. 7 depicts another embodiment of a ship-and-install electronics assembly with multifunctional interface chassis and liquid-fluid heat exchange with a liquid-liquid heat exchanger.

FIG. 8 depicts another embodiment of a ship-and-install electronics assembly with multifunctional interface chassis and liquid-fluid heat exchange in schematic form, showing a form factor compatible with, for example, a server rack.

FIG. 9 depicts another server rack-compatible embodiment of a ship-and-install electronics assembly with multifunctional interface chassis and liquid-fluid heat exchange in schematic form, where the pump and liquid-fluid heat exchanger form an assembly.

FIG. 10 depicts another server rack-compatible embodiment of a ship-and-install electronics assembly with multifunctional interface chassis and liquid-fluid heat exchange in schematic form, where the radiator and liquid-fluid heat exchanger form an assembly.

FIG. 11 depicts another server rack-compatible embodiment of a ship-and-install electronics assembly with multifunctional interface chassis and liquid-fluid heat exchange in schematic form, where the radiator, liquid-fluid heat exchanger, and multifunctional interface form an assembly outside of the server rack.

### DETAILED DESCRIPTION

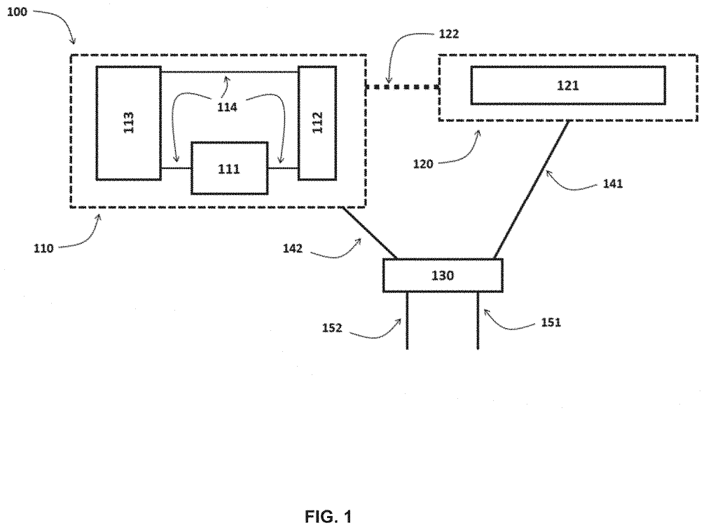

FIG. 1 shows a block diagram of an embodiment of the ship-and-install electronics assembly with multifunctional interface chassis and liquid-fluid heat exchange 100. FIG. 1 displays the constituent parts of the electronics assembly and their interactions, with detailed embodiments of specific arrangements to follow. As shown in FIG. 1, the ship-and-install electronics assembly 100 comprises three subassemblies; namely, a liquid-fluid loop subassembly 110, an electrical circuit subassembly 120, and a multifunctional interface chassis subassembly 130. The liquid-fluid loop subassembly 110 comprises a pump 111, a liquid cooling implement 112, and a liquid-fluid heat exchanger 113. The liquid-fluid loop subassembly 110 also comprises a set of fluid conveyance lines 114, which fluidly connects the pump 111, the liquid cooling implement 112 and the liquid-fluid heat exchanger 113.

The pump 111 increases the fluidic pressure of a liquid coolant so that the coolant can circulate through the liquid-fluid loop. Liquid-fluid heat exchanger 113 is configured to remove the heat from the liquid-fluid loop subassembly 110 by permitting heat transfer from the coolant into another fluid, such as the surrounding atmosphere. The electrical circuit subassembly 120 comprises a heat-generating device 121, which is in thermal communication with the liquid-fluid loop subassembly 110 (the thermal communication is represented in FIG. 1 by the dashed line 122). More specifically, the heat-generating component 121 of the electrical circuit subassembly 120 may be placed in direct thermal communication with the liquid cooling implement 112 of the liquid-fluid loop subassembly 110 so that some of the heat generated by the heat-generated component 121 will flow away from the heat-generating component to be absorbed by the liquid coolant flowing through the liquid cooling implement 112.

In addition to warming up the coolant it receives from the pump 111 via interaction with a heat generating component, the liquid cooling implement 112 accepts coolant flowing out of the pump 111 at a first pressure and exhausts it at a second pressure that is lower than that of the first pressure. This heat is then removed from the liquid-fluid loop subassembly 110 by the operation of the liquid-fluid heat exchanger 113, at which point the coolant may return to the liquid cooling implement 112 via the pump 111 to again absorb more heat from the heat-generating component 121. In this manner, the liquid-fluid loop subassembly 110 provides continuous cooling for the electrical circuit subassembly 120, as well as the heat-generating component 121 therein. Although not shown in FIG. 1, the electrical circuit subassembly 120 may include a plurality of heat-generating components.

The liquid-fluid loop subassembly 110 and electrical circuit subassembly 120 often require many interfaces for proper operation, such as electrical power interfaces, electrical sensor signal interfaces, network interfaces, and structural interfaces. These interfaces are described in greater detail below in connection with the description of exemplary embodiments. The multifunctional interface chassis subassembly 130 serves as a centralized interface for these various interface connection requirements between the assembly 100 and external fixtures. In FIG. 1, for example, the multifunctional interface chassis subassembly 130 may provide an electrical power connection 142 to the liquid-fluid loop subassembly 110 and a network connection 141 to the electrical circuit subassembly 120. The multifunctional interface chassis subassembly 130 also may accept an electrical power connection 152 from an external fixture, and a network connection 151 from an external data communications network fixture (not shown).

In other embodiments, there may be a large variety of combinations of functions interfacing between the multifunctional interface chassis subassembly 130 and either or both of the liquid-fluid loop subassembly 110 and the electrical circuit subassembly 120. For example, an electrical power and network connection may be provided to the liquid-fluid loop subassembly 110, with no connections made to the electrical circuit subassembly 120. The opposite may be true. The multifunctional interface chassis subassembly 130 may provide all of electrical power, electrical sensor signals, data communications and structural interfacing to each of the liquid-fluid loop subassembly 110 and the electrical circuit subassembly 120, always providing connections to appropriate fixtures external to the subassemblies. Any combination of two or more connection types are possible in such embodiments. Preferably, the multifunctional interface chassis subassembly 130 provides a multiplicity of different types of connections.

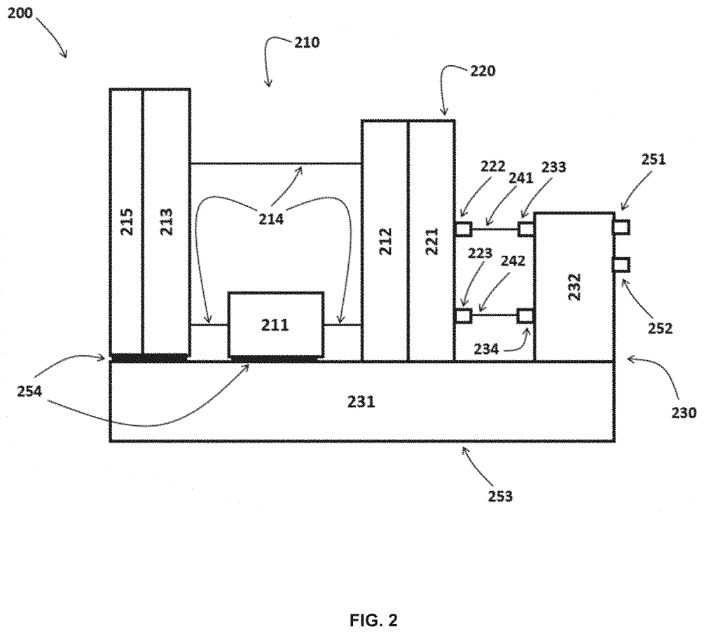

The ship-and-install electronics assembly with multifunctional interface chassis and liquid-fluid heat exchange may be implemented in a variety of different embodiments. Detailed descriptions of some of these embodiments will now be presented with reference to FIGS. 2 through 11.

FIG. 2 depicts an embodiment 200 of the ship-and-install electronics assembly with multifunctional interface chassis and liquid-fluid heat exchange in schematic form. A liquid-fluid loop subassembly 210 comprises a pump 211, a liquid cooling implement 212, a liquid-air heat exchanger 213, and fluid conveyance components 214 connecting each of the liquid-fluid loop subassembly 210 components. An electrical circuit subassembly 220 comprises a heat-generating device 221, placed in thermal communication with the liquid cooling implement 212. The heat-generating device 221 also contains a network port 222 and an electrical power port 223.

A multifunctional interface chassis subassembly 230 comprises a structural base 231 and an electrical circuit box 232. In this case, the liquid-fluid loop subassembly 210 and electrical circuit subassembly 220 are coupled to the structural base 231 to provide a structural interface. In this schematic, the lower surface 253 of the structural base 231 may be preinstalled in the facility (not illustrated in FIG. 2), providing a unified structural interface between the components of the electronics assembly 200 upon connection to the structural base 231. As there are many components in the electronics assembly 200, providing a uniform structural interface makes it easy for end users to receive and install the electronics assembly 200 without needing to come up with structural fixtures for all the different components of the electronics assembly 200.

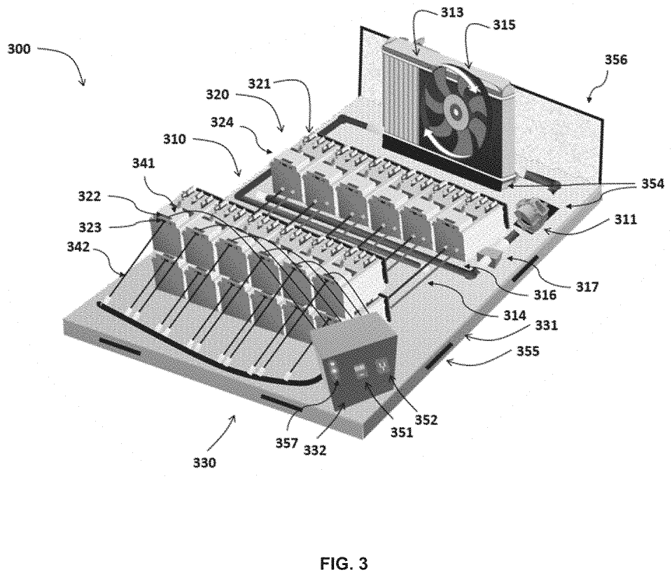

The electrical circuit box 232 has a network port 233 connected to the heat-generating device network port 222 via network cable 241. The electrical circuit box 232 also has an electrical power port 234 that is connected to the heat-generating device electrical power port 223 via power cable 242. Furthermore, the electrical circuit box 232 has a network port 251 and an electrical power port 252 that are available to provide connectivity to a corresponding facility network and power source. Although the schematic in FIG. 2 shows a single heat-generating device 221 in the electrical circuit subassembly 220, it should be appreciated that the electrical circuit subassembly 220 may comprise a multiplicity of electrical components that each require electrical power and/or network connection. In such cases, having a single electrical junction box, constructed according to embodiments of the present invention, to make electrical power and networking connections makes it easy for end users to receive and install electronics assemblies without needing to understand the individual requirements of each connection port in the electrical subassembly 220. This concept will be illustrated and described in greater detail in connection with FIG. 3.

Other components may be included to intelligently implement the ship-and-install electronics assembly with multifunctional interface chassis and liquid-fluid heat exchange. A fan 215 may be placed in proximity to the liquid-air heat exchanger 213 so as to provide airflow to enhance the heat removal capability from the liquid coolant into the surrounding ambient air. Vibration dampeners 254 may be placed under the pump 211 or the fan 215 so as to reduce the effect of vibration generating from the motion of these components. This may be especially helpful to limit the long-term stress on components of the electrical circuit subassembly 220 that may have a resonant frequency near that of the fan 215 or the pump 211 during operation. Vibration dampeners may be placed in other locations in the electronics assembly 200, depending on the types of electrical components included in the electronics assembly 200, as well as the industrial application where the electronics assembly 200 will be used. Vibration dampeners 254 may comprise active vibration dampening systems, passive mechanisms, such as springs, materials dampeners, such as rubbers, silicones, or viscoelastic materials, or any combination of the above.

A fluid filter (not shown) may be included in the liquid-fluid loop subassembly 210 to avoid any potential impact of particles on components of the liquid-fluid loop subassembly 210, such as the pump 211, the liquid cooling implement 212, and/or any seals in the system. A fluid reservoir (also not shown) may also be included in the liquid-fluid loop subassembly 210 to mitigate any potential for gradual loss of fluid from the liquid-fluid loop subassembly 210 due to trace leaks, evaporation, or absorption into fluid conveyance components over time.

The pump 211 may be implemented using centrifugal force, axial flow, positive displacement, or any other suitable means of providing a pressure to drive fluid flow. The pump may be made of a wide variety of materials, whether thermally conductive metals, plastics, high strength metals, or other appropriate materials. The pump may run on any appropriate voltage, whether 12V, 24V, 120V, 240V, 480V, and single or three phase. Although pump 211 is only shown as a single component, it will be appreciated that there could be multiple pumps placed in series or parallel to generate flow of the liquid coolant through the liquid-fluid loop assembly.

Any appropriate liquid coolant may be used. For example, the liquid coolant may comprise a water system, with additives such as algaecides, corrosion inhibitors, or other suitable additives for minimal fluid system maintenance. The liquid coolant also may comprise a water and glycol mixture, such as, for example, a water and glycol mixture comprising 25% or 50% ethylene glycol or propylene glycol, whether for the purpose of freeze protection or fluid longevity. It may also be an oil, such as a dielectric mineral oil.

The liquid-air heat exchanger 213 (also often called a radiator) may take any appropriate form. The liquid-air heat exchanger is typically a high surface area, thermally conductive item that passes the fluid within it. Heat conducts through the radiator and is discharged into the air as the air passes over the radiator exterior surface (e.g., as blown over the radiator by a fan). It may be formed from aluminum or copper, for example, with channels containing sparse or dense fins in thermal communication to allow for the heat to spread into a higher surface area structure.

The heat-generating device 221 may take on many forms. It may be, for example, a circuit board with a plurality of application specific integrated circuits (ASICs). It may be a central processing unit (CPU) or graphics processing unit (GPU) or other similar processing unit. Such processing unit may have a single die or multiple dies. It may be a bare die processor or a processor with a lid or integrated heat spreader. It may be a ball grid array (BGA) or a land grid array (LGA) type processor, or any other geometry for interfacing with a socket or circuit board.

The fluid conveyance components 214 may take on many forms. Fluid conveyance components 214 may comprise fluid conveyance lines, such as, for example, a plurality of interconnected tubes, pipes, or the like. They may be made of any suitable material, such as PVC, CPVC, low durometer plastics, metal or braided metal, or others. They may be connected via any suitable joining technology, such as threads, hose clamps, soldering, push-to-connect, compression, pipe primers and adhesives, or other suitable fittings. Fluid conveyance components 214 may also comprise one or more manifolds. A fluid distribution manifold is a supply or return (or a supply and return) fluid passage where several fluid conveyance lines are aggregated. The manifold keeps the assembly more orderly as multiple conveyance lines stem from a single manifold, reducing the total length of conveyance lines needed.

The contents of the electrical circuit box 232 may be extensive and varied. The electrical circuit box 232 may contain, for example, a network switch, in which a single network cable (e.g. ethernet cable) extending from an external fixture may be plugged into the electrical circuit box 232, where it can be split into a large number of network cables to interface with individual heat-generating components on the electronics assembly 200. The electrical circuit box 232 may also contain control circuitry. For example, if the heat-generating devices contain embedded temperature sensors, and one or more of these temperature sensors detects that a certain temperature threshold is exceeded, then an electrical signal may be sent to the pump 211 or the fan 215, or both the pump 211 and the fan 215, to increase speed in order to provide more aggressive cooling for the heat-generating device until a safe or desired operating temperature is reached. Components such as variable frequency drives (VFDs), or similar components, may assist in this control sequence by way of modulating the pump or fan speed. Other control techniques are possible, such as, for example, adjusting the liquid-fluid loop subassembly 210 or electrical circuit subassembly 220 operation based on the ambient temperature. There may also be relays, electrical contacts, or other such components to implement the appropriate control strategies or power distribution (as explained in more detail below). The signals processed by the electrical circuit box 232 may be analog or digital, single or three phase, low or high voltage, or low or high current.

The electrical circuit box 232 may also contain power conversion or distribution circuitry. It can sometimes be efficient to bring a single power cable at a high voltage to minimize the losses involved in transporting the power from a facility power source to an individual electronic device. However, many electronic components on an electronics assembly do not operate at high voltages. Therefore, the electrical circuit box 232 preferably has power conversion circuitry, such as power supplies and/or step-down transformers, that take in electrical power at one voltage and convert it to output power at another voltage. Similarly, there may be power distribution circuitry, such as busbars, terminal blocks, electrical cabling, or similar components to split an electrical power source to make power available for multiple components.

The electrical circuit box 232 also may contain operational interface circuitry for the end users. For example, there may be one or more status indicating light emitting diodes (LEDs), which show whether the system is on, functioning properly, in a fault condition, or similar. There may be power switches, emergency stop switches, fuses, and associated circuitry to ensure safe operation.

The structural base 231 may take on a variety of forms. The structural base 231 may be formed from any suitable material, such as metal, wood, plastic, or others, balancing the structural requirements with the cost, weight, and convenience. The structural base 231 may also be readily compatible with traditional shipping equipment, such as forklifts or pallet jacks, to allow for easy transport from shipping areas into the end use location. In certain embodiments, a shipping pallet may be an effective option as a structural base 231. In this case, the structural base 231 can double as a shipping base which remains intact as a structural base 231 after delivery. Note that the electrical circuit subassembly 220 and liquid-fluid loop subassembly 213 need not directly attach to the structural base 231; there may be an intermediate structural frame interfacing between the structural base 231 and the plurality of components in the assembly 200. This frame (not shown in FIG. 2) may be made from, for example, extruded aluminum (e.g., 80/20), Unistrut steel, or other common modular frame building materials.

FIG. 3 depicts another embodiment 300 of the ship-and-install electronics assembly 300 with multifunctional interface chassis and liquid-fluid heat exchange according to an embodiment of the present invention. This figure depicts an embodiment that may be used, for example, as a modular assembly for liquid cooling of bitcoin mining electronic assemblies. The structure of FIG. 3 may be used for a variety of different types of electronic components.

A liquid-fluid loop subassembly 310 comprises a pump 311, a plurality of liquid cooling implements, a liquid-air heat exchanger 313, a plurality of fluid conveyance components, including fluid conveyance lines (e.g., tubes) 314 and two fluid distribution manifolds 316, and a fluid filter 317. A fan 315 is placed in proximity to the liquid-air heat exchanger 313 to facilitate airflow for enhanced heat removal capability. An electrical circuit subassembly 320 contains electrical sub-assemblies 324, in this case a total of eighteen, each containing a plurality of heat-generating devices 321.

A multifunctional interface chassis subassembly 330 comprises a structural base 331 and an electrical circuit box 332. The structural base 331 provides structural support for the liquid-fluid loop subassembly 310 and the electrical circuit subassembly 320, for easy interfacing of the assembly 300 with the external structure (not shown) to which the assembly 300 is installed, without needing to provide structural fixtures for every component. The structural base 331 may be placed on the floor, shelves, or any other suitable facility fixture. In FIG. 3, the electrical sub-assemblies 324 are mounted directly to the structural base 331 or indirectly to the structural base 331 via another sub-assembly. In other non-limiting embodiments, one or more frames may be included to assist in providing easy-to-connect structural interfaces between the sub-assemblies and the structural base 331.

The electrical circuit box 332 provides an interface for the eighteen electrical sub-assemblies 324 within electrical circuit assembly 320. Each sub-assembly 324 comprises a network port 322 requiring a network cable 341 and a power plug 323 requiring a power cable 342. The electrical circuit box 332 has a single power port 352 and a single network port 351 for interfacing with the eighteen sub-assemblies 324. This arrangement means the installer only has to make a single network connection and a single power connection via the multifunctional interface chassis subassembly 330 , which makes for easy installation. Of course, there may be more than one power port 352 or network port 351 as is convenient for cost or interface reasons without significantly impacting the ease of installation.

Additional features are included for implementation of the electronics assembly. Vibration dampeners 354 are placed under the pump 311 and the fan 315 to provide better isolation of the assembly 300 from the acceleration of these components. Rectangular slots 355 on the structural base 331, serving as handles in this embodiment, allow the structural base to double as a shipping base to allow for easy transport of the assembly whether onto the shipping truck or within the end use facility. In other embodiments, rectangular slots 355 may serve as spacing for a forklift or pallet jack to insert. Status lights 357 on the multifunctional electrical circuit box 332 provide illuminated indications of the system performance.

The fan 315 may take any suitable form. It may facilitate high volumetric flowrate at low or modest static pressure head requirements. It may be a centrifugal blower, exhaust fan, a tubeaxial fan, or other. It may be a push fan or a pull (suction) fan. Safety/obstructing provisions may be added to the fan blades and/or motor belts of the assembly to avoid accidents with operators. Furthermore, easily swappable air filters, such as mesh screens, pleated panel, or other may be configured so as to catch any dust or particles and avoid damage to the assembly while minimizing impact on the flow profile of the air passing over the liquid-air heat exchanger.

In the case of using a liquid-air heat exchanger 313, there can be major benefits to implementing intentional containment of cool and heated air in the vicinity of the assembly 300. In the electronics assembly 300 depicted in FIG. 3, for example, air baffles 356 are included to control and separate the flows of air. The air baffles 356 provide containment in that they inhibit the air from one side of the baffle from mixing with air on the other side of the baffle. The air baffles 356 may be constructed out of wood, foam, drywall, fiberboard, cardboard, plastic, sheathing, insulation, or other materials. The design of the electronics assembly 300 is such that multiple such assemblies can be aligned next to one another in a row. In so doing, with the liquid-air heat exchangers 313 and fans 315 on a single edge of the structural base 331, adjacent air baffles 356 may form a wall between the side of the assembly 300 that has cool, incoming air and the side that has the hot, exhaust air. By separating these air masses and providing a flow blockage to prevent the air masses from mixing, greater efficiency is achieved. In building construction, this is often called a hot-aisle, cold-aisle construction, but here it is built into the modular assembly form factor. In this way, a hot-aisle/cold-aisle is formed simply by the placement of the modular building blocks to enhance building efficiency. The baffle(s) may be configured to extend from or span one edge of the base to the opposite edge to provide for effective containment.

In some instances, the arrangement of the sub-assemblies 324 may be such as to create air flow paths toward the intake of the fan 315. As one example, the height of nearby components may be lower near the fan inlet and higher away from the fan inlet to allow air to flow into the fan. Yet additional implementations may place the fan above the level of nearby components to create an airflow path with fewer obstructions between the fan and the outer boundary of the system. The sub-assemblies 324 may be arranged in any suitable manner, taking into consideration, for example, air availability to the fan intake, routing of fluid conveyance lines or power/networking cables, structural integrity, shipping form factor, and others.

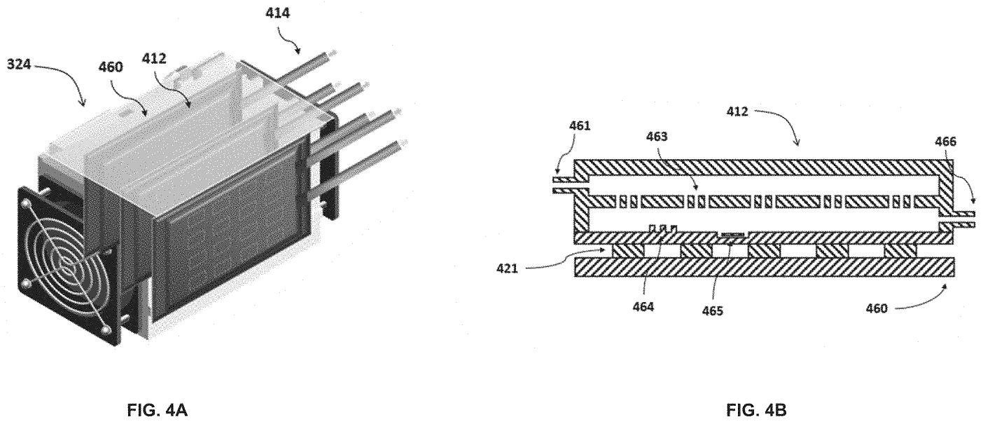

FIGS. 4A and 4B depict external and internal views, respectively, of an exemplary sub-assembly 324 shown in FIG. 3. In FIG. 4A, as a non-limiting example, sub-assembly 324 contains a set of three printed circuit boards 460, attached to three corresponding liquid cooling implements 412. Each liquid cooling implement 412 has two fluid conveyance components 414, in this case, for example, tubes. Note that the fluid conveyance components 414 may be connected serially (i.e. one after another), or in parallel (i.e. side-by-side), with typical tradeoffs in fluid flow rate, pressure drop, and coolant temperature rise as considerations of the implementation known to those skilled in the art.

In FIG. 4B, a liquid cooling implement 412 is shown in cross-section. Circuit board 460 has (in this example) five heat-generating devices 421 disposed on it. They may be, for example, ASICs, CPUs, GPUs, or any other suitable heat-generating component. As to the structure of liquid cooling implement 412, there is an inlet conduit 461 and an outlet conduit 466, with internal features configured to facilitate heat removal from heat-generating components 421. The internal features may comprise: nozzles 463, to generate accelerated fluid flow directed towards the heat-generating components 421; pin fins 464, configured to enhance the area available for heat to spread and come in contact with the coolant fluid; channels 465, sometimes referred to as minichannels or microchannels, configured to provide an enhanced fluid flow profile; or other similar internal features. Of course, these features need not all exist in a single liquid cooling implement, but may be used in combination or separately as is practical for the thermal considerations of the heat-generating components.

As fluid passes through liquid cooling implement 412 from inlet conduit 461 to outlet conduit 466, the fluid picks up heat from the heat-generating components 421 and also undergoes a reduction in pressure due to a number of different causes, including without limitation, friction, contraction, expansion, and/or other pressure-reducing causes. The pump 411 is configured to raise the pressure of the circulating fluid to allow for the fluid to pass through liquid cooling implements 412 to allow for heat removal. Note, there may be thermal interface materials (TIMs) disposed between the heat-generating components 421 and the liquid cooling implement 412. These liquid cooling implements 412 may come pre-installed on the assembly 300 if the electrical circuit subassemblies 324 are first shipped to the assembly facility, or may be installed onto the electrical circuit subassemblies 324 upon arrival at the end use facility.

FIGS. 2 and 3 illustrate representative embodiments of the ship-and-install electronics assembly with multifunctional interface chassis and liquid-fluid heat exchange. As seen in the drawings, liquid cooling assemblies containing heat-generating devices may contain a large plurality of components of varying technical expertise required to assemble and install. Specifically, these systems often require any of electrical power, network, electrical sensor signal, and structural interfacing between the contents of the assembly with a facility fixture external to the assembly. These systems of dense heat-generating components and liquid cooling, therefore, are often very difficult for end users to implement. However, as described, the presence of a modular assembly packaged with a multifunctional interface chassis for simple interfacing with facility fixtures makes for easy installation and operation.

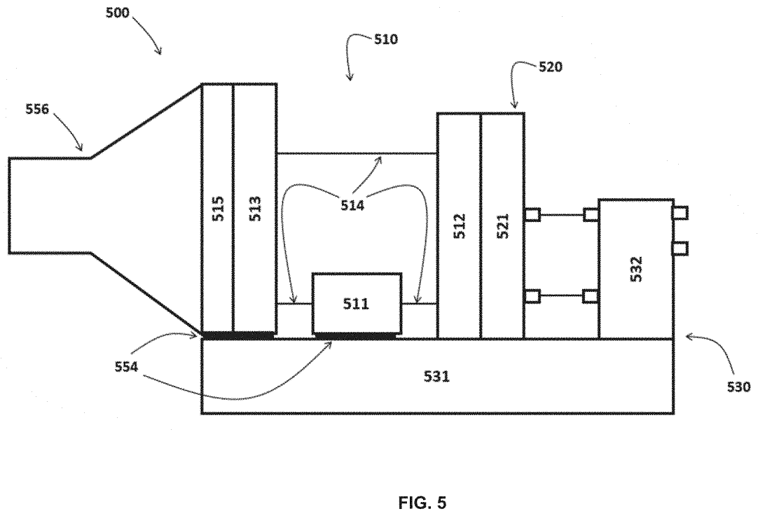

FIG. 5 depicts another embodiment of the ship-and-install electronics assembly 500 with multifunctional interface chassis and liquid-fluid heat exchange in schematic form. Assembly 500 includes a different method of air containment, either adding to or replacing the air baffles 356 in FIG. 3. In FIG. 5, a liquid-fluid loop assembly 510 comprises a pump 511, a liquid cooling implement 512, a liquid-air heat exchanger 513, and fluid conveyance components 514. A fan 515 is placed in proximity to the liquid-air heat exchanger 513. An electrical circuit assembly 520 comprises a heat-generating component 521, placed in thermal communication with liquid cooling implement 512 to facilitate heat transfer from the heat-generating element into the liquid coolant circulating in liquid-fluid loop 510. A multifunctional interface chassis 530 comprises a structural base 531 providing a structural interface between the assembly 500 components and the shelf or floor it is placed upon. The chassis 530 also comprises an electrical circuit box 532, providing power, control signal, or network connectivity between the assembly 500 and facility power or network fixtures. Vibration dampening components 554 are disposed between pump 511 and fan 515 and the structural base 531 to limit acceleration of other assembly components.

As heat passes through the liquid-air heat exchanger 513, the fan 515 generates air flow to remove heat from the liquid coolant and raise the temperature of the flowing air. In facilities that may be implementing more than one of such an assembly in close proximity, this heated air could be detrimental to a neighboring system, as neighboring heat-generating devices may run hotter if the air used for heat exchange is at a higher temperature at the fan intake. Alternatively, the heated air could be useful in providing a waste heat function, such as heating the building or incorporating into low temperature industrial processes.

Regardless of the reason, an air duct 556 may be included so as to allow for containment of the heated exhaust air, and routed in an intentional manner so as to control the direction of the fan air flow. In many scenarios, the air duct 556 will neck down to provide a smaller air flow passageway than the liquid-air heat exchanger 513, so as to not require an unnecessarily large or expensive ducting system once the liquid-air heat exchange has been completed.

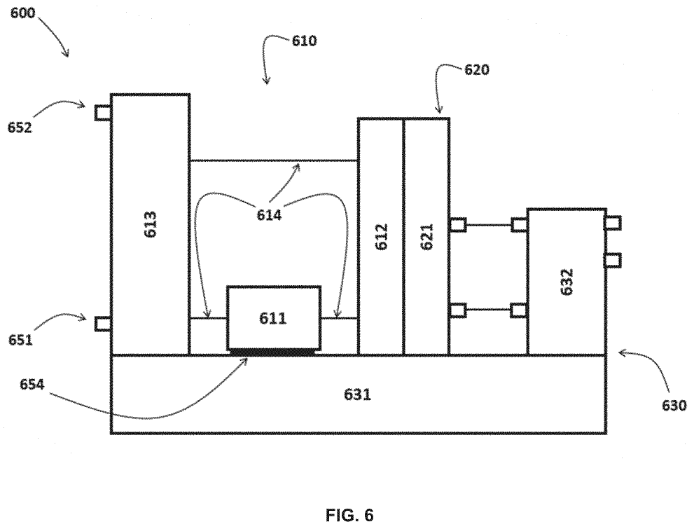

FIG. 6 depicts another embodiment of the ship-and-install electronics assembly 600 with multifunctional interface chassis and liquid-fluid heat exchange in schematic form. Assembly 600 includes a different method of liquid-fluid heat exchange, now incorporating a liquid-liquid heat exchanger 613 instead of a liquid-air heat exchanger. In FIG. 6, a liquid-fluid loop subassembly 610 comprises a pump 611, a liquid cooling implement 612, a liquid-liquid heat exchanger 613, and fluid conveyance components 614. An electrical circuit subassembly 620 comprises a heat-generating component 621, placed in thermal communication with the liquid cooling implement 612 to facilitate heat transfer from the heat-generating element into the liquid coolant circulating through the liquid-fluid loop 610. A multifunctional interface chassis 630 comprises a structural base 631 providing a structural interface between the assembly 600 components and the shelf or floor it is placed upon. The chassis 630 also comprises an electrical circuit box 632, providing power or network connectivity between the assembly 600 and facility power and network fixtures. Vibration dampening components 654 are disposed between pump 611 and the structural base 631 to limit acceleration of other assembly components.

On the liquid-liquid heat exchanger 613, there are inlet and outlet connections 651 and 652 for providing conveyance of a second liquid into the liquid-liquid heat exchanger to interact with the liquid-fluid loop assembly 610 and carry heat away. Note that the liquid in the liquid coolant loop 610 and the liquid passing through connections 651 and 652 typically do not mix, to maintain separate fluid systems. Often, large facilities housing computing equipment or hardware have built-in facility water systems, which provide infrastructure for circulating water throughout the facility and chilling it via a chiller, cooling tower, or thermosiphon located on the roof or outside. In the case of a facility water system, sometimes it can save energy or provide a service to the building when the facility liquid loop accepts the heat from the assembly 600. The heat could then be repurposed for building heating or other such waste heat capture applications.

The liquid-liquid heat exchanger 613 may take any appropriate form. It may be made from thermally conductive metals so as to facilitate efficient thermal transfer between the liquid coolant in the liquid-fluid loop assembly with that of the facility liquid-fluid loop. It may take on the form of a metal with strong material compatibility properties, such as stainless steel, to avoid galvanic corrosion with other materials in the liquid-fluid loop assembly. It may be a brazed plate heat exchanger, a shell and tube heat exchanger, a spiral plate heat exchanger, or any appropriate alternative. It may be sized to match and total thermal power characteristics of the electrical circuit assembly 620 and/or the flow rate of the facility liquid-fluid loop system or liquid-fluid loop assembly 610.

It may also be advantageous to include both a liquid-liquid heat exchanger and a liquid-air heat exchanger assembly with a fan onto the assembly 600. This may provide flexibility to the end user as far as what their facility is outfitted with, making it easy to install whether or not they have a facility liquid cooling system, for example. It also may serve as a fail-safe, wherein if, for example one of the liquid-fluid heat exchangers experienced a failure, the other could turn on and provide continuous operation while the other component is being serviced. Similarly, if the fluid facility system needs to be serviced, the liquid-air heat exchanger could turn on. These could be plumbed in series or in parallel.

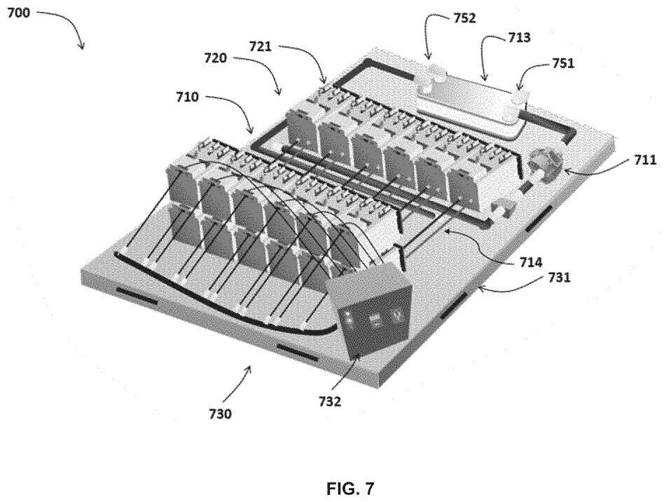

FIG. 7 depicts another embodiment of the ship-and-install electronics assembly 700 with multifunctional interface chassis and liquid-fluid heat exchange. Assembly 700 mirrors that shown in FIG. 3, but now includes a liquid-liquid heat exchanger 713 instead of a liquid-air heat exchanger 313. In FIG. 7, a liquid-fluid loop assembly 710 comprises a pump 711, a liquid cooling implement (not shown in FIG. 7, but see FIG. 4B), a liquid-liquid heat exchanger 713, and fluid conveyance components 714. An electrical circuit assembly 720 comprises a heat-generating component 721, placed in thermal communication with liquid cooling implement (see FIG. 4) to facilitate heat transfer from the heat-generating element into the liquid coolant circulating in liquid-fluid loop 710. A multifunctional interface chassis subassembly 730 comprises a structural base 731 providing a structural interface between the assembly 700 components and the facility structural fixture (not shown) it is placed upon. The chassis subassembly 730 also comprises an electrical circuit box 732, providing power, control signal, and/or network connectivity between the assembly 700 and facility fixtures. Fluid ports 751 and 752 provide an interface for a facility liquid system to exchange heat with the liquid-fluid loop assembly 710. As was discussed in FIG. 3, electrical circuit box 732 forming part of multifunctional interface 730 allows for easy installation by minimizing the number of connections to facility fixtures required, despite many electronic sub-assemblies requiring electrical power or network connectivity.

The embodiments depicted so far in FIGS. 2-7 have been modular, standalone assemblies. Other embodiments may readily interface with other common electronics equipment, such as computing racks, while maintaining modularity and ease of shipping and install.

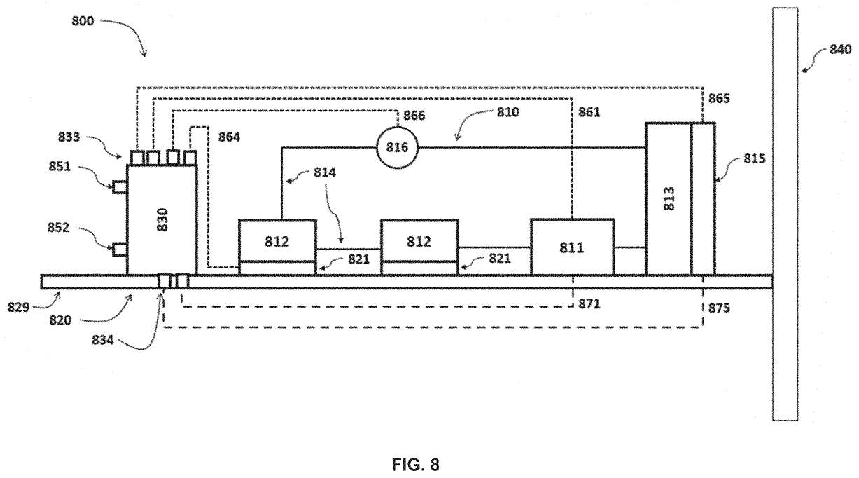

For example, FIG. 8 depicts an embodiment of a ship-and-install electronics assembly 800 with multifunctional interface chassis and liquid-fluid heat exchange in a server rack form factor, in schematic form. A liquid-fluid loop assembly 810 comprises a pump 811, liquid cooling implements 812, a liquid-air heat exchanger 813, fluid conveyance components 814, and a sensor 816. A fan 815 is mounted in proximity to the liquid-air heat exchanger 813. An electrical circuit assembly, comprising a printed circuit board 829 and heat-generating components 821, is disposed in a chassis (not shown) compatible with a computing rack 840. A multifunctional interface chassis 830 comprises electrical signal and/or network ports 833 for communicating electrical signals to and from components of the liquid-fluid loop 810 and electrical circuit assembly 820. The multifunctional interface chassis 830 also comprises electrical power ports 834 for providing power to components of the liquid-fluid loop assembly 810. The multifunctional interface chassis 830 also comprises network port 851 and power port 852 for accepting power and network from an external fixture, such as the rack network switch and/or rack power distribution circuitry. Specifically, the multifunctional interface chassis 830 may provide for example, a control signal 861 to the pump 811 to control its speed; an electrical power signal 871 to the pump 811 to provide power; a control signal 865 to fan 815 to control its duty cycle; a power signal 875 to fan 815 to provide power; a sensor signal 866 from sensor 816 to read its data, such as an analog or digital signal; and a sensor signal 864 from heat-generating component 821, such as an analog or digital signal from embedded sensors on the heat-generating component.

In operation, the pump 811 elevates the pressure of the coolant. The coolant travels through liquid cooling implements 812 to remove heat from heat-generating components 821 on circuit board 829 in electrical circuit assembly 820. Coolant is then passed through the liquid air heat exchanger 813, where air is pulled through the fan 815 and takes heat away from the liquid coolant to continue circulating at steady state and maintain the heat-generating components at safe operating temperatures. As the air picked up heat from the coolant, the exhaust air is elevated in temperature, and is exhausted out the back of the rack. This could be part of a hot aisle / cold aisle construction, to make for efficient containment of the heated air so as to not impact neighboring assemblies whether in the same rack (e.g., above or below) or in neighboring racks. The multifunctional interface chassis 830 accepts power from an external fixture via power port 852, provides power to components of the assembly 800, reads sensor data from components of the assembly 800, provides control signals to components of the assembly 800, receives and routes control signals through network port 851, and/or sends sensor data out through network port 851.

The multifunctional interface chassis subassembly 830 may comprise varied electrical circuit components. It may include power distribution circuitry, control circuitry, power conversion circuitry, network switches, relays, contactors, or any other appropriate circuitry. The multifunctional interface chassis subassembly 830 may process analog or digital signals, low or high voltage or current, or single or three phase power.

Sensor 816 may comprise of any suitable sensor, including but not limited to temperature sensors (e.g., thermocouples, RTDs) for measuring the temperature of the coolant, a flow meter for measuring the system flow rate, a pressure transducer for measuring the pressure or pressure drop through the system, a conductivity meter or similar for measuring coolant electrical properties, or other such coolant properties. These signals may provide feedback for sending signals to other components in the liquid-fluid loop subassembly 810, such as, for example, controlling the fan speed based on the temperature of the coolant, or controlling the pump speed based on the measured flow rate. Sensor 816 may also take the form of a leak sensor. This may be a capacitive sensor, conductive sensor, leak wire, imaging technique, or other approach. If a leak from the fluid circulating system is detected, a signal is produced and provided to the multifunctional interface chassis or panel. This may, for example, be used in a control sequence to put the system in a safe mode or turn power off to the system. There may be more than one sensor included in the system, and each sensor may provide more than one data output.

Heat-generating component 821 may comprise a CPU, GPU, ASIC, field programmable gate array (FPGA), or any other such processor. Note that although two heat-generating components 821 are shown in FIG. 8, there may be any number of heat-generating components, perhaps as few as one or as many as four, or perhaps more. There may be non-processor related heat-generating components 821. There are sometimes control circuits on pumps or sensors that comprise components that generate heat, for which a flowing liquid coolant in liquid-fluid loop assembly 810 will provide heat rejection.

Network port 851 may, for example, communicate local sensor signals from the assembly to a centralized control panel of a computing facility, for long term monitoring or getting a readout of current assembly status. Alternatively, a centralized control panel may send signals to the network port 851 to be processed by the multifunctional interface chassis 830 and route the appropriate signal to the component, such as increasing the pump speed in the case of an abnormally warm day sensed beyond the extents of the assembly.

Liquid cooling implements 812 may comprise internal features configured to assist in heat transfer out of the heat-generating component and into the coolant, such as nozzles, pin fins, channels, or other such features. The liquid cooling implements accept pressurized coolant via the pump and exhaust at a pressure lower than that it was accepted due to losses from friction, contraction, expansion, and other such pressure drop sources. A thermal interface material may be used to provide intimate thermal communication between the liquid cooling implements 812 and the heat-generating components 821.

The overall assembly may take a number of different shapes and sizes. It may fit within one rack unit (e.g., 1U), or it may be in 2U or 4U or any whole or fractional rack unit. This may depend on the total power level of the heat-generating elements.

Other liquid-fluid loop components may be included in the loop. A filter may be included to minimize the impact of particles on components of the liquid-fluid loop assembly. A reservoir may also be included to provide coolant in the case of slow fluid loss through any variety of mechanisms. There may also be drain / fill ports or valves in the liquid-fluid loop assembly to provide for fluid loss, as well. The liquid-fluid heat exchanger may be liquid-air (also referred to as a radiator) or may be liquid-liquid.

Separately, fluid connections may be included upstream and downstream of the heat exchanger and, when connected to a separate fluid system, used to bypass the heat exchanger. This may be done, for example, for installations where a facility-level coolant system is available. Sensors may be integrated (for example, conductive link sensors, capacitive sensors, fluid flow sensors, or the like) to detect when a separate fluid system is connected, and flow is being bypassed. When flow is being bypassed and not significantly dependent on the heat exchanger, the heat exchanger fans may be reduced in speed or turned off to enable more efficient operation.

As shown in the diagram, the assembly 800 is internal to the rack 840, therefore provisions may be made on the printed circuit board 829 to provide fasteners locations and/or allotted space for the various components. The signals may be communicated through electrical cables or wires or may be built into the circuit board via connected copper traces.

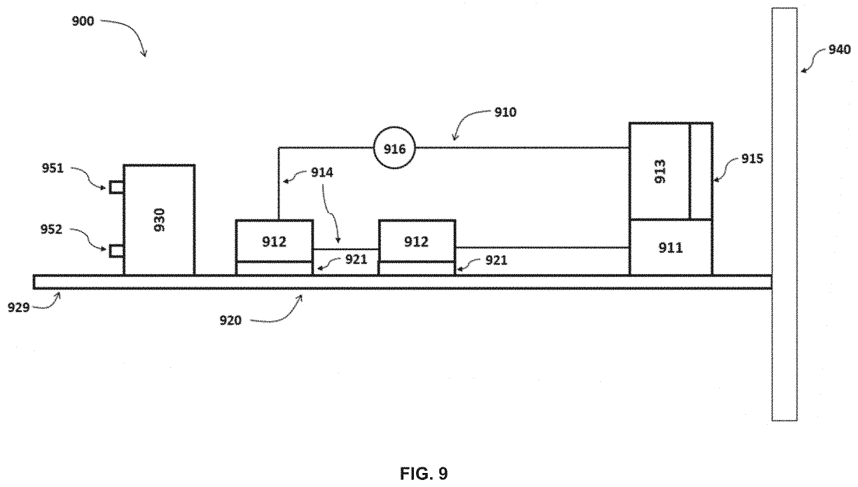

FIG. 9 depicts another embodiment of the ship-and-install electronics assembly 900 with multifunctional interface chassis and liquid-fluid heat exchange in schematic form. FIG. 9 also displays an assembly 900 internal to the rack 940, but this time configured such that the pump and liquid-air heat exchanger form an assembly. A liquid-fluid loop assembly 910 comprises a pump 911, liquid cooling implements 912, a liquid-air heat exchanger 913 (near or integral with pump 911), liquid conveyance components 914, and a sensor 916. A fan 915 is mounted in proximity to the liquid-air heat exchanger 913. An electrical circuit assembly 920 comprises a printed circuit board 929 and heat-generating elements 921. A multifunctional interface chassis subassembly 930 comprises power, electrical, and network ports (not shown) to interface with various components of the assembly 900 as enumerated, for example, in FIG. 8. The multifunctional interface chassis subassembly 930 also comprises a network port 951 to provide network connectivity for, for example, communication of signals or control commands in and out of the assembly, and a power port 952, to provide power to the assembly 900. This configuration may provide spacing benefits, for a more compact system and/or fewer fastener or space provisions required in the PCB design. This configuration may also allow for a single actuator providing a driving force for both the fans and the pump, if configured appropriately.

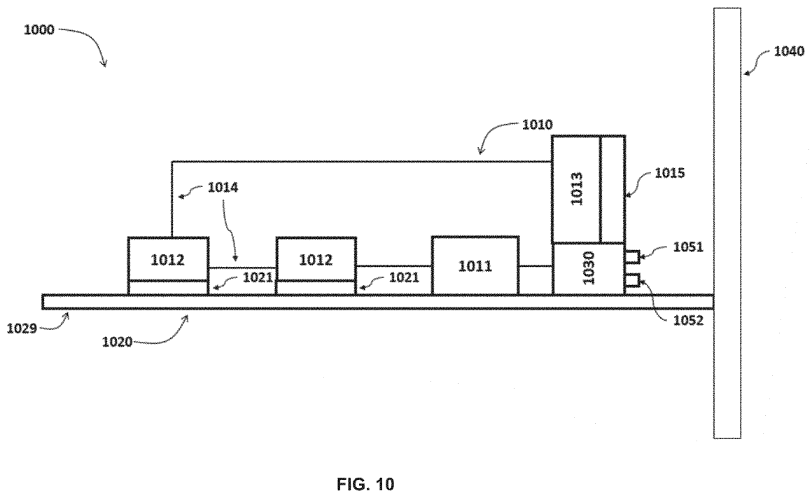

FIG. 10 depicts yet another embodiment of the ship-and-install electronics assembly 1000 with multifunctional interface chassis and liquid-fluid heat exchange in schematic form. FIG. 10 also displays an assembly 1000 internal to the rack 1040, but this time configured such that the multifunctional interface and liquid-air heat exchanger form an assembly. A liquid-fluid loop subassembly 1010 comprises a pump 1011, liquid cooling implements 1012, a liquid-air heat exchanger 1013, and liquid conveyance components 1014. A fan 1015 is mounted in proximity to the liquid-air heat exchanger 1013. An electrical circuit subassembly 1020 comprises a printed circuit board 1029 and heat-generating elements 1021. A multifunctional interface chassis subassembly 1030 comprises power, electrical, and network ports (not shown) to interface with various components of the assembly 1000 as enumerated, for example, in FIG. 8. The multifunctional interface chassis subassembly 1030 also comprises a network port 1051 to provide network connectivity for, for example, communication of signals or control commands in and out of the assembly, and a power port 1052, to provide power to the assembly. In this embodiment, the multifunctional interface is near or integral with the liquid-air heat exchanger 1013. This configuration may provide spacing benefits, for a more compact system and/or fewer fastener or space provisions required in the PCB design.

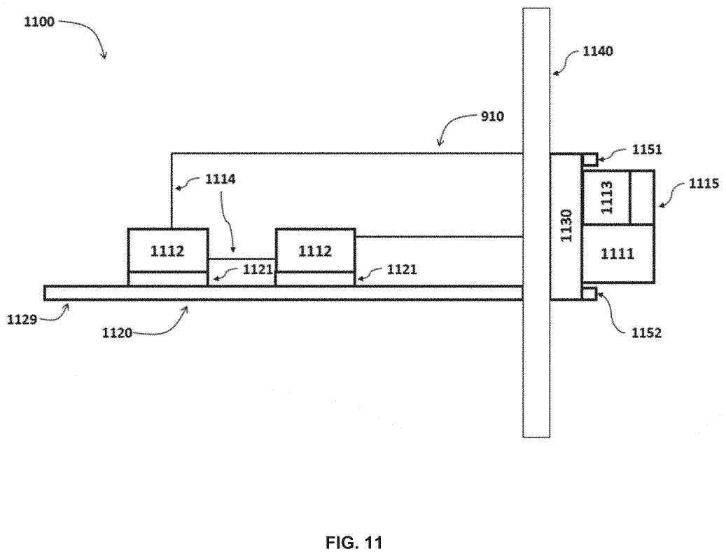

FIG. 11 depicts still another embodiment of the ship-and-install electronics assembly 1100 with multifunctional interface chassis and liquid-fluid heat exchange in schematic form. Unlike FIGS. 8-10, components of the assembly 1100 are configured to be placed outside of the rack volume. A liquid-fluid loop subassembly 1110 comprises a pump 1111, liquid cooling implements 1112, a liquid-air heat exchanger 1113, and liquid conveyance components 1114. A fan 1115 is mounted in proximity to the liquid-air heat exchanger 1113. An electrical circuit assembly 1120 comprises a printed circuit board 1129 and heat-generating elements 1121. A multifunctional interface chassis subassembly 1130 comprises power, electrical, and network ports (not shown) to interface with various components of the assembly 1100 as enumerated, for example, in FIG. 8. The multifunctional interface chassis 1130 also comprises a network port 1151 to provide network connectivity for, for example, communication of signals or control commands in and out of the assembly, and a power port 1152, to provide power to the assembly. In this embodiment, the multifunctional interface is near or integral with the liquid-air heat exchanger 1113 and the pump 1111 and is located on the backside of the rack interface 1140. In this configuration, the multifunctional interface chassis subassembly 1130 also provides a structural interface for the pump 1111 and the liquid-air heat exchanger 1113, making for a convenient single assembly for mounting on any rack hole patterns or fasteners available on the rack 1140. The fluid conveyance components may enter through passthroughs in the server chassis or rack panel, or quick disconnect fittings may be included on either side to form the full assembly.

Thus, in this embodiment, the multifunctional interface chassis provides all of structural, electrical sensor signal, electrical power, and network communication between the assembly 1100 and external fixtures. This configuration may allow for more flexible integration with many different PCB designs, as specific design provisions on the PCB may not be required. It may also be preferred for retrofitting systems as no changes may be needed to the internal circuitry.

In summary, various embodiments of a ship-and-install electronics assembly with multifunctional interface chassis and liquid-fluid heat exchange were presented. A liquid-fluid loop subassembly contains a pump, a liquid cooling implement, a liquid-fluid heat exchanger, and fluid conveyance components. An electrical circuit subassembly contains a heat-generating component. A multifunctional interface chassis subassembly facilitates at least two of structural, electrical power, electrical sensor signal, and network communication between the assembly and fixtures external to the assembly. The multifunctional interface chassis subassembly may comprise a single component or may be an assembly of components. It may have a single port for each function, or may have multiple ports per function. Regardless, the multifunctional interface serves to simplify the installation and interfacing such that liquid cooled assemblies for dense electronics may be proliferated.

The present disclosure is not to be limited in scope by the specific embodiments described herein. Indeed, other various embodiments of and modifications to the present disclosure, in addition to those described herein, will be apparent to those or ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

what is claimed is:

1. An electronics assembly, comprising:
(a) an electrical circuit subassembly comprising a heat-generating electrical component;
(b) a liquid-fluid loop subassembly comprising
(i) a pump configured to pressurize a liquid coolant,
(ii) a liquid cooling implement in fluidic communication with the pump and in direct thermal communication with the heat-generating electrical component, the liquid cooling implement being configured to receive the liquid coolant from the pump at a first pressure and exhaust the liquid coolant at a second pressure that is lower than the first pressure, so that the liquid coolant will absorb heat generated by the heat-generated component as the liquid coolant flows through the liquid cooling implement, and
(iii) a liquid-fluid heat exchanger in fluidic communication with the liquid cooling implement and the pump, the liquid-fluid heat exchanger being configured to receive the liquid coolant from liquid cooling implement and remove the heat absorbed by the liquid coolant; and
(c) a multifunctional interface chassis subassembly electrically connected to the electrical circuit subassembly, the liquid-fluid loop subassembly and the liquid-fluid heat exchanger, the multifunctional interface chassis subassembly comprising an electrical power port configured to be connected to an active external power fixture;
(d) wherein, when the electrical power port on the multifunctional interface chassis subassembly is connected to the active external power fixture, the multifunctional interface chassis subassembly will receive electrical power from the active external power fixture and deliver the electrical power to at least one of the electrical circuit subassembly, the liquid-fluid loop subassembly and the liquid-fluid heat exchanger.

2. The electronics assembly of claim 1, wherein:
(a) the multifunctional interface chassis subassembly is communicatively coupled to the electrical circuit subassembly, the liquid-fluid loop subassembly, or both, and
(b) the multifunctional interface chassis subassembly further comprises a network port configured to be communicatively coupled to an external data communications network;
(c) wherein, when the network port on the multifunctional interface chassis subassembly is connected to the external data communications network, the multifunctional interface chassis subassembly will provide a data communications channel to carry data communications signals between the external data communications network and the electrical circuit subassembly, between the external data communications network and the liquid-fluid loop subassembly, or both.

3. The electronics assembly of claim 1, wherein the liquid cooling implement comprises an internal feature to increase a rate that the liquid cooling implement absorbs heat from the heat-generating electrical component.

4. The electronics assembly of claim 3, wherein the internal feature of the liquid cooling implement comprises at least one nozzle configured to generate jets of liquid coolant.

5. The electronics assembly of claim 3, wherein the internal feature of the liquid cooling implement comprises at least one fin configured to increase a contact area between the liquid cooling implement and the liquid coolant.

6. The electronics assembly of claim 3, wherein the internal feature of the liquid cooling implement comprises at least one channel configured to enhance a flow profile of the liquid coolant as it flows through the liquid cooling implement.

7. The electronics assembly of claim 1, further comprising a vibration damper to reduce vibrations of the electrical circuit subassembly.

8. The electronics assembly of claim 1, wherein the liquid-fluid heat exchanger is a liquid-air heat exchanger.

9. The electronics assembly of claim 8, further comprising a fan to accelerate air flowing through the liquid-air heat exchanger for increased heat removal.

10. The electronics assembly of claim 8, further comprising an air containment system.

11. The electronics assembly of claim 10, where the air containment system comprises at least one baffle.

12. The electronics assembly of claim 10, where the air containment system comprises at least one duct.

13. The electronics assembly of claim 1, wherein the liquid-fluid heat exchanger is a liquid-liquid heat exchanger.

14. The electronics assembly of claim 1, wherein the liquid-fluid heat exchanger comprises both a liquid-air heat exchanger and a liquid-liquid heat exchanger.

15. The electronics assembly of claim 1, wherein the liquid-fluid loop subassembly further comprises a filter that removes particulate matter from the liquid coolant.

16. The electronics assembly of claim 1, wherein the liquid-fluid loop subassembly further comprises a reservoir to store the liquid coolant.

17. The electronics assembly of claim 1, wherein the heat-generating electrical component comprises a processor.

18. The electronics assembly of claim 17, wherein the processor comprises:
(a) an application specific integrated circuit (ASIC);
(b) or a central processing unit (CPU),
(c) or a graphics processing unit (GPU).

19. The electronics assembly of claim 1, further comprising a fluid distribution manifold to provide the fluidic communication between the pump, the liquid cooling implement and the liquid-fluid heat exchanger.

20. The electronics assembly of claim 1, further comprising a sensor configured to detect a signal indicative of an availability of data generated by the the electronics assembly.

21. The electronics assembly of claim 20, wherein the sensor is located in the liquid-fluid loop subassembly.

22. The electronics assembly of claim 20, wherein the sensor is located in the electrical circuit subassembly.

23. The electronics assembly of claim 20, wherein the sensor is configured to detect a signal indicating that a temperature threshold has been crossed.

24. The electronics assembly of claim 20, wherein the sensor is configured to detect a signal indicating an availability of fluid flow data from the electronics assembly.

25. The electronics assembly of claim 20, wherein the sensor is configured to detect a signal indicating that there is a leak in the liquid-fluid loop subassembly.

26. The electronics assembly of claim 1, further comprising an electrical cable that transmits an electrical signal between the electrical circuit subassembly and the multifunctional interface chassis subassembly, wherein the electrical signal represents sensor data collected by the electrical circuit subassembly.

27. The electronics assembly of claim 1, wherein the multifunctional interface chassis subassembly comprises a structural base for (1) the electrical circuit subassembly, (2) the liquid-fluid loop subassembly, or (3) both the electrical circuit subassembly and the liquid-fluid loop subassembly.

28. The electronics assembly of claim 27, wherein the structural base is configured to interface with a pallet jack, a forklift, or both.

29. The electronics assembly of claim 27, wherein the structural base is a shipping pallet.

30. The electronics assembly of claim 1, wherein the multifunctional interface chassis subassembly comprises an electrical circuit.

31. The electronics assembly of claim 30, wherein the electrical circuit on the multifunctional interface chassis subassembly comprises a network switch.

32. The electronics assembly of claim 30, wherein the electrical circuit of the multifunctional interface chassis subassembly comprises a power supply.

33. The electronics assembly of claim 30, wherein the electrical circuit on the multifunctional interface chassis subassembly comprises power distribution circuitry.

34. The electronics assembly of claim 30, wherein the electrical circuit of the multifunctional interface chassis subassembly comprises status LEDs.

35. The electronics assembly of claim 30, wherein the electrical circuit of the multifunctional interface chassis subassembly comprises a control system.

36. The electronics assembly of claim 35, wherein the control system receives sensor data from the liquid-fluid loop subassembly, the electrical circuit subassembly, or both.
